(19) United States
(12) Patent Application Publication
(10) Pub. No.: US 2007/0092736 A1
(43) Pub. Date: Apr. 26, 2007

(54) Method of making light emitting device with silicon-containing encapsulant

(75) Inventors: Larry D. Boardman, Woodbury, MN (US); D. Scott Thompson, Woodbury, MN (US); Catherine A. Leatherdale, St. Paul, MN (US); Andrew J. Ouderkirk, Woodbury, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/255,711

(22) Filed: Oct. 21, 2005

(51) Int. Cl. B32B 27/04; H01L 21/56; C08L 83/04; C08G 77/04

(52) U.S. Cl. 428/447; 438/127; 524/861; 524/588

(57) ABSTRACT

A method of making a light emitting device is disclosed herein. The method includes the steps of: (A) providing a light emitting diode; and (B) contacting the light emitting diode with a photopolymerizable composition having: a silicon-containing resin comprising silicon-bonded hydrogen and aliphatic unsaturation; a first metal-containing catalyst that may be activated by actinic radiation; and a second metal-containing catalyst that may be activated by heat but not the actinic radiation. The method may further include the step of: (C) applying actinic radiation of 700 nm or less to initiate hydrosilylation within the silicon-containing resin. The method may also include the step of: (D) heating the photopolymerizable composition to less than 150° C. to further initiate hydrosilylation, or (D) simultaneously applying actinic radiation and heat.

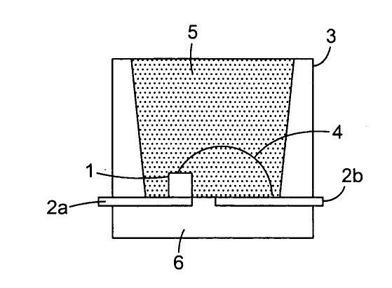

### CROSS REFERENCE TO RELATED APPLICATIONS

This application claims priority from U.S. Provisional Application Ser. No. ______ by Boardman et al., entitled “Method of Making Light Emitting Device with Silicon-Containing Encapsulant”, filed Oct. 17, 2005.

This application is related to: commonly assigned, co-pending U.S. patent application Ser. No. ______ by Boardman et al., entitled “Method of Making Light Emitting Device with Silicon-Containing Encapsulant”, and filed of even date herewith (Docket 61384US003), which claims priority from U.S. Provisional Application Ser. No. ______ by Boardman et al., entitled “Method of Making Light Emitting Device with Silicon-Containing Encapsulant”, filed Oct. 17, 2005 (Docket 61384US002); and commonly assigned, co-pending U.S. patent application Ser. No. ______ by Boardman et al., entitled “Method of Making Light Emitting Device with Silicon-Containing Encapsulant”, and filed Oct. 17, 2005 (Docket 60158US006), which is a continuation-in-part of U.S. patent application Ser. No. 10/993,460, filed Nov. 18, 2004, now pending.

### FIELD OF THE INVENTION

The invention relates to a method of making a light emitting device. More particularly, the invention relates to a method of making a light emitting device having a light emitting diode (LED) and a silicon-containing encapsulant.

### BACKGROUND

Typical encapsulants for LEDs are organic polymeric materials. Encapsulant lifetime is a significant hurdle holding back improved performance of high brightness LEDs. Conventional LEDs are encapsulated in epoxy resins and, when in use, tend to yellow over time reducing the LED brightness and changing the color rendering index of the light emitted from the light emitting device. This is particularly important for white LEDs. The yellowing of the epoxy is believed to result from decomposition induced by the high operating temperatures of the LED and/or absorption of UV-blue light emitted by the LED.

A second problem that can occur when using conventional epoxy resins is stress-induced breakage of the wire bond on repeated thermal cycling. High brightness LEDs can have heat loads on the order of 100 Watts per square centimeter. Since the coefficients of thermal expansion of epoxy resins typically used as encapsulants are significantly larger than those of the semiconductor layers and the moduli of the epoxies can be high, the embedded wire bond can be stressed to the point of failure on repeated heating and cooling cycles.

Thus, there is a need for new photochemically stable and thermally stable encapsulants for LEDs that reduce the stress on the wire bond over many temperature cycles. In addition, there is a need for encapsulants with relatively rapid cure mechanisms in order to accelerate manufacturing times and reduce overall LED cost.

### SUMMARY

A method of making a light emitting device is disclosed herein. The method comprising the steps of: (A) providing a light emitting diode; and (B) contacting the light emitting diode with a photopolymerizable composition comprising: a silicon-containing resin comprising silicon-bonded hydrogen and aliphatic unsaturation; a first metal-containing catalyst that may be activated by actinic radiation; and a second metal-containing catalyst that may be activated by heat but not the actinic radiation.

Also disclosed herein is the above method further comprising the step of: (C) applying actinic radiation at a wavelength of 700 nm or less to initiate hydrosilylation within the silicon-containing resin, thereby forming a first encapsulant, wherein hydrosilylation comprises reaction between the silicon-bonded hydrogen and the aliphatic unsaturation. This method may further comprise the step of: (D) heating the first encapsulant to less than 150° C. to further initiate hydrosilylation, thereby forming a second encapsulant. Optionally, the step (D) may be: simultaneously applying actinic radiation at a wavelength of 700 nm and heat to less than 150° C. to further initiate hydrosilylation, thereby forming a second encapsulant.

The silicon-containing resin may comprise one or more organosiloxanes, such as an organosiloxane having aliphatic unsaturation and silicon-bonded hydrogen in the same molecule, or a first organosiloxane having aliphatic unsaturation and a second organosiloxane having silicon-bonded hydrogen. The first metal-containing catalyst and/or the second metal-containing catalyst may comprise platinum. Photopolymerizable compositions employed in the above-described methods are also disclosed herein. In addition, light emitting devices prepared according to the above-described methods are disclosed herein.

Light emitting devices disclosed herein comprise an encapsulant with any one or more of the following desirable features: high refractive index, photochemical stability, thermal stability, formable by relatively rapid cure mechanisms, and formable at relatively low temperatures.

These and other aspects of the invention will be apparent from the detailed description below. In no event, however, should the above summary be construed as a limitation on the claimed subject matter, which subject matter is defined solely by the attached claims, as may be amended during prosecution.

### BRIEF DESCRIPTION OF THE DRAWING

The invention may be more completely understood in consideration of the following detailed description and examples in connection with the FIGURE described below. The FIGURE is an illustrative example and, in no event, should be construed as a limitation on the claimed subject matter, which subject matter is defined solely by the claims set forth herein.

The FIGURE is a schematic diagram of a light emitting device capable of being prepared according to the disclosed method.

### DETAILED DESCRIPTION

A method of making a light emitting device is disclosed. Referring to the FIGURE, LED 1 is mounted on a metallized contact 2a disposed on a substrate 6 in a reflecting cup 3. LED 1 has one electrical contact on its lowermost surface and another on its uppermost surface, the latter of which is connected to a separate electrical contact 2b by a wire bond 4. A power source can be coupled to the electrical contacts to energize the LED. Encapsulant 5 encapsulates the LED.

Silicon-containing encapsulants are known in the art and are advantageous because of their thermal and photochemical stability. These encapsulants typically comprise organosiloxanes that are cured either by acid-catalyzed condensation reactions between silanol groups bonded to the organosiloxane components or by metal-catalyzed hydrosilylation reactions between groups incorporating aliphatic unsaturation and silicon-bonded hydrogen which are bonded to the organosiloxane components. In the first instance, the curing reaction is relatively slow, sometimes requiring many hours to proceed to completion. In the second instance, desirable levels of cure normally require temperatures significantly in excess of room temperature. For example, US Patent Application Publication US 2004/0116640 A1 states that such compositions are “. . . preferably cured by heating at about 120 to 180° C. for about 30 to 180 minutes.”

A method for preparing a light emitting device with an LED sealed within a silicon-containing encapsulant is disclosed. The method utilizes a photopolymerizable composition that comprises a silicon-containing resin capable of undergoing hydrosilylation. The photopolymerizable composition also comprises first and second metal-containing catalysts wherein the first metal-containing catalyst may be activated with actinic radiation, and the second by heat but not the actinic radiation. The combination of these catalysts provides: (1) the ability to cure the photopolymerizable composition without subjecting the LED, the substrate to which it is attached, or any other materials present in the package or system, to potentially harmful levels of actinic radiation and/or high temperatures, (2) the ability to formulate one-part encapsulating compositions that display long working times (also known as bath life, shelf life, or pot life), and (3) the ability to form the encapsulant on demand at the discretion of the user.

As described above, the method of making a light emitting device comprises the steps of: (A) providing a light emitting diode; and (B) contacting the light emitting diode with a photopolymerizable composition comprising: a silicon-containing resin comprising silicon-bonded hydrogen and aliphatic unsaturation; a first metal-containing catalyst that may be activated by actinic radiation; and a second metal-containing catalyst that may be activated by heat but not the actinic radiation. Also disclosed herein is the above method further comprising the step of: (C) applying actinic radiation at a wavelength of 700 nm or less to initiate hydrosilylation within the silicon-containing resin, thereby forming a first encapsulant, wherein hydrosilylation comprises reaction between the silicon-bonded hydrogen and the aliphatic unsaturation.

Actinic radiation may be applied until the desired properties of the first encapsulant are obtained. For example, actinic radiation may be applied until the first encapsulant is qualitatively tack free and elastomeric, or until the first encapsulant is qualitatively a tacky gel. The latter may be desirable in order to control settling of any additional components such as particles, phosphors, etc. which may be present. Controlled settling of the particles or phosphors may be used to achieve specific useful spatial distributions of the particles or phosphors within the encapsulant. For example, the method may allow controlled settling of particles enabling formation of a gradient refractive index distribution that may enhance LED efficiency or emission pattern. It may also be advantageous to allow partial settling of phosphor such that a portion of the encapsulant is clear and other portions contain phosphor. In this case, the clear portion of encapsulant can be shaped to act as a lens for the emitted light from the phosphor.

When used, the actinic radiation has a wavelength of 700 nm or less which includes visible and UV light. The actinic radiation may also have a wavelength of 600 nm or less, from 200 to 600 nm, or from 250 to 500 nm. The actinic radiation may have a wavelength of at least 200 nm, for example, at least 250 nm. Examples of sources of actinic radiation include tungsten halogen lamps, xenon arc lamps, mercury arc lamps, incandescent lamps, germicidal lamps, and fluorescent lamps. In certain embodiments, the source of actinic radiation is the LED, such that applying actinic radiation comprises activating the LED. Actinic radiation may be applied when the photopolymerizable composition is at a temperature of less than 120° C., less than 60° C., or less than 25° C.

After the step (C) in which actinic radiation is applied, a step (D) may be used to heat the first encapsulant to a temperature of less than 150° C. in order to further initiate hydrosilylation, thereby forming a second encapsulant. In this case, heat may be applied until the desired properties of the second encapsulant are obtained. This heating step may be used to control settling of particles or phosphors as described above, accelerate formation of the encapsulant, or decrease the amount of time the encapsulant is exposed to actinic radiation during the previous step. Heating the first encapsulant to a temperature of less than 120° C., less than 60° C., or less than 25° C. may also be useful. Any heating means may be used such as an infrared lamp, a forced air oven, or a heating plate. In some applications, step (D) may comprise providing room temperature conditions to further initiate hydrosilylation. In other applications, step (D) may comprise simultaneously applying actinic radiation at a wavelength of 700 nm and heat to less than 150° C. to further initiate hydrosilylation, thereby forming a second encapsulant. In this case, it is useful that the actinic radiation applied in this step (D) may have the same wavelength or range of wavelengths as the actinic radiation used in step (C).

The desired properties of the first and second encapsulants may be controlled by the extent to which hydrosilylation occurs. The first and/or second encapsulants may be liquids, gels, elastomers, or non-elastic solids. In general, hydrosilylation, i.e., the addition reaction between aliphatic unsaturation and silicon-bonded hydrogen, takes place to a lesser extent in the first encapsulant as compared to the second encapsulant. For example, hydrosilylation in the first encapsulant may comprise reaction between the silicon-bonded hydrogen and at least 5 mole percent of the aliphatic unsaturation. In some cases, it may be desirable for hydrosilylation in the first encapsulant to comprise reaction between the silicon-bonded hydrogen and at least 60 mole percent of the aliphatic unsaturation. In other cases, it may be desirable for hydrosilylation in the second encapsulant to comprise reaction between the silicon-bonded hydrogen and at least 60 mole percent of the aliphatic unsaturation.

In general, whenever actinic radiation and/or heat is used, the source, amount of time, temperature, etc. are all variables that may be optimized depending on the particular chemistry of the silicon-containing resin (monomer, oligomer, polymer, etc.), its reactivity, the amount present in the light emitting device, as well as on the types and amounts of the metal-containing catalysts. For the second encapsulant, it may be desirable to optimize these variables such that hydrosilylation occurs in less than 30 minutes, less than 10 minutes, less than 5 minutes, or less than 1 minute. In certain embodiments, less than 10 seconds may be desirable.

The silicon-containing resin can include monomers, oligomers, polymers, or mixtures thereof. The silicon-containing resin may comprise one or more organosiloxanes; for example, the one or more organosiloxanes may comprise an organosiloxane having aliphatic unsaturation and silicon-bonded hydrogen in the same molecule, or the one or more organosiloxanes comprises a first organosiloxane having aliphatic unsaturation and a second organosiloxane having silicon-bonded hydrogen.

Preferred silicon-containing resins are selected such that they provide an encapsulant that is photostable and thermally stable. Herein, photostable refers to a material that does not chemically degrade upon prolonged exposure to actinic radiation, particularly with respect to the formation of colored or light absorbing degradation products. Herein, thermally stable refers to a material that does not chemically degrade upon prolonged exposure to heat, particularly with respect to the formation of colored or light absorbing degradation products.

In some embodiments, it may be desirable for the photopolymerizable composition to have a refractive index of at least 1.34, or at least 1.50, so that the first and second encapsulants have similar refractive indices. The desired refractive index may be provided by the silicon-containing resin, by additional components present in the photopolymerizable composition, or both.

Examples of suitable silicon-containing resins are disclosed, for example, in U.S. Pat. Nos. 6,376,569 (Oxman et al.), U.S. Pat. No. 4,916,169 (Boardman et al.), U.S. Pat. No. 6,046,250 (Boardman et al.), U.S. Pat. No. 5,145,886 (Oxman et al.), U.S. Pat. No. 6,150,546 (Butts), and in U.S. Pat. Appl. Nos. 2004/0116640 (Miyoshi).

In one embodiment, the silicon-containing resin comprises at least two sites of aliphatic unsaturation, such as alkenyl or alkynyl groups, bonded to silicon atoms in a molecule and an organohydrogensilane and/or organohydrogenpolysiloxane component having at least two hydrogen atoms bonded to silicon atoms in a molecule. In either case, the aliphatic unsaturation may or may not be directly bonded to silicon. In other embodiments, the silicon-containing resin comprises first and second organosiloxanes. The organosiloxane containing aliphatic unsaturation may be a base polymer (i.e., the major organosiloxane component in the composition.) Preferred silicon-containing resins are organopolysiloxanes. Organopolysiloxanes are known in the art and are disclosed in such patents as U.S. Pat. No. 3,159,662 (Ashby), U.S. Pat. No. 3,220,972 (Lamoreauz), U.S. Pat. No. 3,410,886 (Joy), U.S. Pat. No. 4,609,574 (Keryk), U.S. Pat. No. 5,145,886 (Oxman, et. al), and U.S. Pat. No. 4,916,169 (Boardman et. al).

Organopolysiloxanes that contain aliphatic unsaturation are preferably linear, cyclic, or branched organopolysiloxanes comprising units of the formula R¹ₐR²_{b}SiO_{(4-a-b)/2} wherein: R¹ is a monovalent, straight-chained, branched or cyclic, unsubstituted or substituted hydrocarbon group that is free of aliphatic unsaturation and has from 1 to 18 carbon atoms; R² is a monovalent hydrocarbon group having aliphatic unsaturation and from 2 to 10 carbon atoms; a is 0, 1, 2, or 3; b is 0, 1, 2, or 3; and the sum a+b is 0, 1, 2, or 3; with the proviso that there is on average at least 1 R² present per molecule.

Organopolysiloxanes that contain aliphatic unsaturation preferably have an average viscosity of at least 5 mPa·s at 25° C.

Examples of suitable R¹ groups are alkyl groups such as methyl, ethyl, n-propyl, iso-propyl, n-butyl, iso-butyl, tert-butyl, n-pentyl, iso-pentyl, neo-pentyl, tert-pentyl, cyclopentyl, r-hexyl, cyclohexyl, n-octyl, 2,2,4-trimethylpentyl, n-decyl, n-dodecyl, and n-octadecyl; aromatic groups such as phenyl or naphthyl; alkaryl groups such as 4-tolyl; aralkyl groups such as benzyl, 1-phenylethyl, and 2-phenylethyl; and substituted alkyl groups such as 3,3,3-trifluoro-n-propyl, 1,1,2,2-tetrahydroperfluoro-n-hexyl, and 3-chloro-n-propyl. In some embodiments, at least 90 mole percent of the R¹ groups are methyl. In some embodiments, at least 20 mole percent of the R¹ groups are aryl, aralkyl, alkaryl, or combinations thereof.

Examples of suitable R² groups are alkenyl groups such as vinyl, 5-hexenyl, 1-propenyl, allyl, 3-butenyl, 4-pentenyl, 7-octenyl, and 9-decenyl; and alkynyl groups such as ethynyl, propargyl and 1-propynyl. In the present invention, groups having aliphatic carbon-carbon multiple bonds include groups having cycloaliphatic carbon-carbon multiple bonds.

Organopolysiloxanes that contain silicon-bonded hydrogen are preferably linear, cyclic or branched organopolysiloxanes comprising units of the formula R¹ₐH_{c}SiO_{(4-a-c)/2} wherein: R¹ is as defined above; a is 0, 1, 2, or 3; c is 0, 1, or 2; and the sum of a+c is 0, 1, 2, or 3; with the proviso that there is on average at least 1 silicon-bonded hydrogen atom present per molecule.

Organopolysiloxanes that contain silicon-bonded hydrogen preferably have an average viscosity of at least 5 mPa·s at 25° C.

Organopolysiloxanes that contain both aliphatic unsaturation and silicon-bonded hydrogen preferably comprise units of both formulae R¹ₐR²_{b}SiO_{(4-a-b)/2} and R¹ₐH_{c}SiO_{(4-a-c)/2}. In these formulae, R¹, R², a, b, and c are as defined above, with the proviso that there is an average of at least 1 group containing aliphatic unsaturation and 1 silicon-bonded hydrogen atom per molecule.

The molar ratio of silicon-bonded hydrogen atoms to aliphatic unsaturation in the silicon-containing resin (particularly the organopolysiloxane resin) may range from 0.5 to 10.0 mol/mol, preferably from 0.8 to 4.0 mol/mol, and more preferably from 1.0 to 3.0 mol/mol.

For some embodiments, organopolysiloxane resins described above wherein a significant fraction of the R¹ groups are phenyl or other aryl, aralkyl, or alkaryl are preferred, because the incorporation of these groups provides materials having higher refractive indices than materials wherein all of the R¹ radicals are, for example, methyl.

The first and second metal-containing catalysts are known in the art and typically include complexes of precious metals such as platinum, rhodium, iridium, cobalt, nickel, and palladium. In some embodiments, the first metal-containing catalyst and/or the second metal-containing catalyst comprise platinum. In some embodiments, two or more of the first and/or second metal-containing catalysts may be used.

A variety of first catalysts are disclosed, for example, in U.S. Pat. No. 6,376,569 (Oxman et al.), U.S. Pat. No. 4,916,169 (Boardman et al.), U.S. Pat. No. 6,046,250 (Boardman et al.), U.S. Pat. No. 5,145,886 (Oxman et al.), U.S. Pat. No. 6,150,546 (Butts), U.S. Pat. No. 4,530,879 (Drahnak), U.S. Pat. No. 4,510,094 (Drahnak) U.S. Pat. No. 5,496,961 (Dauth), U.S. Pat. No. 5,523,436 (Dauth), U.S. Pat. No. 4,670,531 (Eckberg), as well as International Publication No. WO 95/025735 (Mignani).

In some embodiments, the first metal-containing catalyst may be selected from the group consisting of Pt(II) β-diketonate complexes (such as those disclosed in U.S. Pat. No. 5,145,886 (Oxman et al.), (η⁵-cyclopentadienyl)tri(σ-aliphatic)platinum complexes (such as those disclosed in U.S. Pat. No. 4,916,169 (Boardman et al.) and U.S. Pat. No. 4,510,094 (Drahnak)), and C₇₋₂₀-aromatic substituted (η⁵-cyclopentadienyl)tri(σ-aliphatic)platinum complexes (such as those disclosed in U.S. Pat. No. 6,150,546 (Butts).

Suitable catalysts that may be used as the second metal-containing catalyst are disclosed, for example, in U.S. Pat. No. 2,823,218 (Speier et al), U.S. Pat. No. 3,419,593 (Willing), U.S. Pat. Nos. 3,715,334 and 3,814,730 (Karstedt), U.S. Pat. No. 4,421,903 (Ashby), U.S. Pat. No. 3,220,972 (Lamoreaux), U.S. Pat. No. 4,613,215 (Chandra et al), and U.S. Pat. No. 4,705,765 (Lewis). In some embodiments, the second metal-containing catalyst comprises a platinum vinylsiloxane complex.

As described above, the amounts of the metal-containing catalysts used in the photopolymerizable composition may depend on a variety of factors such as whether actinic radiation and/or heat is being used, the radiation source, amount of time, temperature, etc., as well as on the particular chemistry of the silicon-containing resin, its reactivity, the amount present in the light emitting device, etc. In some embodiments, the first and second metal-containing catalysts may be independently used in an amount of at least 1 part, and more preferably at least 5 parts, per one million parts of the photopolymerizable composition. Such catalysts are preferably included in amounts of no greater than 1000 parts of metal, and more preferably no greater than 200 parts of metal, per one million parts of the photopolymerizable composition.

In addition to the silicon-containing resins and catalysts, the photopolymerizable composition may comprise one or more additives selected from the group consisting of nonabsorbing metal oxide particles, semiconductor particles, phosphors, sensitizers, photoinitiators, antioxidants, catalyst inhibitors, pigments, adhesion promoters, and solvent. For example, the photopolymerizable composition may comprise one or more phosphors. If used, such additives are used in amounts to produced the desired effect.

Particles that are included within the photopolymerizable composition can be surface treated to improve dispersibility of the particles in the resin. Examples of such surface treatment chemistries include silanes, siloxanes, carboxylic acids, phosphonic acids, zirconates, titanates, and the like. Techniques for applying such surface treatment chemistries are known.

Nonabsorbing metal oxide and semiconductor particles can optionally be included in the photopolymerizable composition to increase the refractive index of the encapsulant. Suitable nonabsorbing particles are those that are substantially transparent over the emission bandwidth of the LED. In this regard, substantially transparent refers to the particles are not capable of absorbing light emitted from the LED. That is, the optical bandgap of the semiconductor or metal oxide particles is greater than the photon energy of light emitted from the LED. Examples of nonabsorbing metal oxide and semiconductor particles include, but are not limited to, Al₂O₃, ZrO₂, TiO₂, V₂O₅, ZnO, SnO₂, ZnS, SiO₂, and mixtures thereof, as well as other sufficiently transparent non-oxide ceramic materials such as semiconductor materials including such materials as ZnS, CdS, and GaN. Silica (SiO₂), having a relatively low refractive index, may also be useful as a particle material in some applications, but, more significantly, it can also be useful as a thin surface treatment for particles made of higher refractive index materials, to allow for more facile surface treatment with organosilanes. In this regard, the particles can include species that have a core of one material on which is deposited a material of another type. If used, such nonabsorbing metal oxide and semiconductor particles are preferably included in the photopolymerizable composition in an amount of no greater than 85 wt-%, based on the total weight of the photopolymerizable composition. Preferably, the nonabsorbing metal oxide and semiconductor particles are included in the photopolymerizable composition in an amount of at least 10 wt-%, and more preferably in an amount of at least 45 wt-%, based on the total weight of the photopolymerizable composition. Generally the particles can range in size from 1 nanometer to 1 micron, preferably from 10 nanometers to 300 nanometers, more preferably, from 10 nanometers to 100 nanometers. This particle size is an average particle size, wherein the particle size is the longest dimension of the particles, which is a diameter for spherical particles. It will be appreciated by those skilled in the art that the volume percent of metal oxide and/or semiconductor particles cannot exceed 74 percent by volume given a monomodal distribution of spherical particles.

Phosphors can optionally be included in the photopolymerizable composition to adjust the color emitted from the LED. As described herein, a phosphor consists of a fluorescent material. The fluorescent material could be inorganic particles, organic particles, or organic molecules or a combination thereof. Suitable inorganic particles include doped garnets (such as YAG:Ce and (Y,Gd)AG:Ce), aluminates (such as Sr₂Al₁₄O₂₅:Eu, and BAM:Eu), silicates (such as SrBaSiO:Eu), sulfides (such as ZnS:Ag, CaS:Eu, and SrGa₂S₄:Eu), oxy-sulfides, oxy-nitrides, phosphates, borates, and tungstates (such as CaWO₄). These materials may be in the form of conventional phosphor powders or nanoparticle phosphor powders. Another class of suitable inorganic particles is the so-called quantum dot phosphors made of semiconductor nanoparticles including Si, Ge, CdS, CdSe, CdTe, ZnS, ZnSe, ZnTe, PbS, PbSe, PbTe, InN, InP, InAs, AlN, AlP, AlAs, GaN, GaP, GaAs and combinations thereof. Generally, the surface of each quantum dot will be at least partially coated with an organic molecule to prevent agglomeration and increase compatibility with the binder. In some cases the semiconductor quantum dot may be made up of several layers of different materials in a core-shell construction. Suitable organic molecules include fluorescent dyes such as those listed in U.S. Pat. No. 6,600,175 (Baretz et al.). Preferred fluorescent materials are those that exhibit good durability and stable optical properties. The phosphor layer may consist of a blend of different types of phosphors in a single layer or a series of layers, each containing one or more types of phosphors. The inorganic phosphor particles in the phosphor layer may vary in size (e.g., diameter) and they may be segregated such that the average particle size is not uniform across the cross-section of the siloxane layer in which they are incorporated. If used, the phosphor particles are preferably included in the photopolymerizable composition in an amount of no greater than 85 wt-%, and in an amount of at least 1 wt-%, based on the total weight of the photopolymerizable composition. The amount of phosphor used will be adjusted according to the thickness of the siloxane layer containing the phosphor and the desired color of the emitted light.

Sensitizers can optionally be included in the photopolymerizable composition to both increase the overall rate of the curing process (or hydrosilylation reaction) at a given wavelength of initiating radiation and/or shift the optimum effective wavelength of the initiating radiation to longer values. Useful sensitizers include, for example, polycyclic aromatic compounds and aromatic compounds containing a ketone chromaphore (such as those disclosed in U.S. Pat. No. 4,916,169 (Boardman et al.) and U.S. Pat. No. 6,376,569 (Oxman et al.)). Examples of useful sensitizers include, but are not limited to, 2-chlorothioxanthone, 9,10-dimethylanthracene, 9,10-dichloroanthracene, and 2-ethyl-9,10-dimethylanthracene. If used, such sensitizers are preferably included in the photopolymerizable composition in an amount of no greater than 50,000 parts by weight, and more preferably no greater than 5000 parts by weight, per one million parts of the composition. If used, such sensitizers are preferably included in the photopolymerizable composition in an amount of at least 50 parts by weight, and more preferably at least 100 parts by weight, per one million parts of the composition.

Photoinitiators can optionally be included in the photopolymerizable composition to increase the overall rate of the curing process (or hydrosilylation reaction). Useful photoinitiators include, for example, monoketals of α-diketones or α-ketoaldehydes and acyloins and their corresponding ethers (such as those disclosed in U.S. Pat. No. 6,376,569 (Oxman et al.)). If used, such photoinitiators are preferably included in the photopolymerizable composition in an amount of no greater than 50,000 parts by weight, and more preferably no greater than 5000 parts by weight, per one million parts of the composition. If used, such photoinitiators are preferably included in the photopolymerizable composition in an amount of at least 50 parts by weight, and more preferably at least 100 parts by weight, per one million parts of the composition.

Catalyst inhibitors can optionally be included in the photopolymerizable composition to further extend the usable shelf life of the composition. Catalyst inhibitors are known in the art and include such materials as acetylenic alcohols (for example, see U.S. Pat. No. 3,989,666 (Niemi) and U.S. Pat. No. 3,445,420 (Kookootsedes et al.)), unsaturated carboxylic esters (for example, see U.S. Pat. No. 4,504,645 (Melancon), U.S. Pat. No. 4,256,870 (Eckberg), U.S. Pat. No. 4,347,346 (Eckberg), and U.S. Pat. No. 4,774,111 (Lo)) and certain olefinic siloxanes (for example, see U.S. Pat. No. 3,933,880 (Bergstrom), U.S. Pat. No. 3,989,666 (Niemi), and U.S. Pat. No. 3,989,667 (Lee et al.). If used, such catalyst inhibitors are preferably included in the photopolymerizable composition in an amount not to exceed the amount of the metal-containing catalyst on a mole basis.

LEDs

The silicon-containing materials described herein are useful as encapsulants for light emitting devices that include an LED. LED in this regard refers to a diode that emits light, whether visible, ultraviolet, or infrared. It includes incoherent epoxy-encased semiconductor devices marketed as “LEDs”, whether of the conventional or super-radiant variety. Vertical cavity surface emitting laser diodes are another form of LED. An “LED die” is an LED in its most basic form, i.e., in the form of an individual component or chip made by semiconductor wafer processing procedures. The component or chip can include electrical contacts suitable for application of power to energize the device. The individual layers and other functional elements of the component or chip are typically formed on the wafer scale, the finished wafer finally being diced into individual piece parts to yield a multiplicity of LED dies.

The silicon-containing materials described herein are useful with a wide variety of LEDs, including monochrome and phosphor-LEDs (in which blue or UV light is converted to another color via a fluorescent phosphor). They are also useful for encapsulating LEDs packaged in a variety of configurations, including but not limited to LEDs surface mounted in ceramic or polymeric packages, which may or may not have a reflecting cup, LEDs mounted on circuit boards, and LEDs mounted on plastic electronic substrates.

LED emission light can be any light that an LED source can emit and can range from the UV to the infrared portions of the electromagnetic spectrum depending on the composition and structure of the semiconductor layers. Where the source of the actinic radiation is the LED itself, LED emission is preferably in the range from 350-500 nm. The silicon-containing materials described herein are particularly useful in surface mount and side mount LED packages where the encapsulant is cured in a reflector cup. They are also particularly useful with LED designs containing a top wire bond (as opposed to flip-chip configurations). Additionally, the silicon containing materials can be useful for surface mount LEDs where there is no reflector cup and can be useful for encapsulating arrays of surface mounted LEDs attached to a variety of substrates.

The silicon-containing materials described herein are resistant to thermal and photodegradation (resistant to yellowing) and thus are particularly useful for white light sources (i.e., white light emitting devices). White light sources that utilize LEDs in their construction can have two basic configurations. In one, referred to herein as direct emissive LEDs, white light is generated by direct emission of different colored LEDs. Examples include a combination of a red LED, a green LED, and a blue LED, and a combination of a blue LED and a yellow LED. In the other basic configuration, referred to herein as LED-excited phosphor-based light sources (PLEDs), a single LED generates light in a narrow range of wavelengths, which impinges upon and excites a phosphor material to produce visible light. The phosphor can comprise a mixture or combination of distinct phosphor materials, and the light emitted by the phosphor can include a plurality of narrow emission lines distributed over the visible wavelength range such that the emitted light appears substantially white to the unaided human eye. The phosphor may be applied to the LED as part of the photopolymerizable composition. Also, the phosphor may be applied to the LED in a separate step, for example, the phosphor may be coated onto the LED die prior to contacting the light emitting diode with the photopolymerizable composition.

An example of a PLED is a blue LED illuminating a phosphor that converts blue to both red and green wavelengths. A portion of the blue excitation light is not absorbed by the phosphor, and the residual blue excitation light is combined with the red and green light emitted by the phosphor. Another example of a PLED is an ultraviolet (UV) LED illuminating a phosphor that absorbs and converts UV light to red, green, and blue light. Organopolysiloxanes where the R¹ groups are small and have minimal UV absorption, for example methyl, are preferred for UV light emitting diodes. It will be apparent to one skilled in the art that competitive absorption of the actinic radiation by the phosphor will decrease absorption by the photoinitiators slowing or even preventing cure if the system is not carefully constructed.

### EXAMPLES

Mounting Blue LED Die in a Ceramic Package

Into a Kyocera package (Kyocera America, Inc., Part No. KD-LA2707-A) was bonded a Cree XT die (Cree Inc., Part No. C460XT290-0119-A) using a water based halide flux (Superior No. 30, Superior Flux & Mfg. Co.). The LED device was completed by wire bonding (Kulicke and Soffa Industries, Inc. 4524 Digital Series Manual Wire Bonder) the Cree XT die using 1 mil gold wire. Prior to encapsulation, each device was tested using an OL 770 Spectroradiometer (Optronics Laboratories, Inc.) with a constant current of 20 mA. The peak emission wavelength of the LED was 458-460 nm.

### Example 1

To 10.00 g of H₂C═CH—Si(CH₃)₂O—[Si(CH₃)₂O]₈₀—[Si(C₆H₅)₂O]₂₆—Si(CH₃)₂—CH═CH₂ (purchased from Gelest as PDV-2331) was added a 25 μL aliquot of a solution, the solution comprising 10 mg of a solution of Pt{[H₂C═CH—Si(CH₃)₂]₂O} (3M Company) in [H₂C═CH—Si(CH₃)₂]₂O at a concentration of 20 wt. % platinum, in 10 mL of heptane. (This catalyst may be prepared using methods analogous to those described in U.S. Pat. No. 3,715,334 (Karstedt); U.S. Pat. No. 3,814,730 (Karstedt); U.S. Pat. No. 3,159,662 (Ashby); Angew. Chem. Int. Ed. Eng. (1991) 30, pp. 438-440; Organometallics (1995), 14, 2202-2213; or Journal of Organometallic Chemistry (1995) 492 C11-C13.) To 1.00 g of this composition was added an additional 1.50 g of PDV-2331, 0.26 g of H(CH₃)₂SiO—[Si(CH₃)HO]_{15—[Si(CH}₃)(C₆H₅)O]₁₅—Si(CH₃)₂H (purchased from Gelest as HPM-502), and a 25 μL aliquot of a solution of 33 mg of CH₃CpPt(CH₃)₃ in 1 mL of toluene. The mixture was degassed under vacuum, and the final composition was labeled Encapsulant B.

Into a blue LED device described above was placed a small drop of Encapsulant B using the tip of a syringe needle such that the LED and wire bond were covered and the device was filled to level to the top of the reflector cup. The siloxane encapsulant was irradiated for 3 minutes under a UVP Blak-Ray Lamp Model XX-15 fitted with two 16-inch Philips F15T8/BL 15W bulbs emitting at 365 nm from a distance of 20 mm from the encapsulated LED. The encapsulant was judged fully cured, tack free and elastomeric by probing with the tip of a tweezer.

### Example 2

A blue LED device was filled with Encapsulant B as described in Example 1. The siloxane encapsulant was irradiated as described in Example 1 but only for 15 seconds. The filled LED device containing the irradiated encapsulant was then placed on a hotplate set at 100° C. After 30 seconds the encapsulant was judged fully cured, tack free and elastomeric by probing with the tip of a tweezer. Prior to heating at 100° C. the encapsulant was an incompletely cured tacky gel.

### Example 3

A blue LED device was filled with Encapsulant B as described in Example 1. The siloxane-filled LED device was placed on a hotplate set at 100° C. After 5 minutes the encapsulant was judged fully cured, tack free and elastomeric by probing with the tip of a tweezer.

### Example 4

A blue LED device was filled with Encapsulant B as described in Example 1. After standing at room temperature overnight, the encapsulant was judged fully cured, tack free and elastomeric by probing with the tip of a tweezer.

Various modifications and alterations to the invention will become apparent to those skilled in the art without departing from the scope and spirit of the invention. It should be understood that the invention is not intended to be unduly limited by the illustrative embodiments and examples set forth herein, and that such examples and embodiments are presented by way of example only with the scope of the invention intended to be limited only by the claims set forth herein as follows.

What is claimed is:

1. A method of making a light emitting device, the method comprising the steps of:
(A) providing a light emitting diode; and
(B) contacting the light emitting diode with a photopolymerizable composition comprising:
a silicon-containing resin comprising silicon-bonded hydrogen and aliphatic unsaturation;
a first metal-containing catalyst that may be activated by actinic radiation; and
a second metal-containing catalyst that may be activated by heat but not the actinic radiation.

2. The method of claim 1, further comprising the step of:
(C) applying actinic radiation at a wavelength of 700 nm or less to initiate hydrosilylation within the silicon-containing resin, thereby forming a first encapsulant, wherein hydrosilylation comprises reaction between the silicon-bonded hydrogen and the aliphatic unsaturation.

3. The method of claim 2, further comprising the step of:
(D) heating the first encapsulant to less than 150° C. to further initiate hydrosilylation, thereby forming a second encapsulant.

4. The method of claim 2 wherein hydrosilylation comprises reaction between the silicon-bonded hydrogen and at least 5 mole percent of the aliphatic unsaturation.

5. The method of claim 2 wherein hydrosilylation comprises reaction between the silicon-bonded hydrogen and at least 60 mole percent of the aliphatic unsaturation.

6. The method of claim 3 wherein hydrosilylation comprises reaction between the silicon-bonded hydrogen and at least 60 mole percent of the aliphatic unsaturation.

7. The method of claim 3 wherein reaction of the aliphatic unsaturation and the silicon-bonded hydrogen occurs in less than 30 minutes.

8. The method of claim 7 wherein the reaction occurs in less than 10 minutes.

9. The method of claim 8 wherein the reaction occurs in less than 5 minutes.

10. The method of claim 9 wherein the reaction occurs in less than 1 minute.

11. The method of claim 10 wherein the reaction occurs in less than 10 seconds.

12. The method of claim 2 wherein applying actinic radiation comprises activating the light emitting diode.

13. The method of claim 2 wherein the photopolymerizable composition is at a temperature of less than 120° C.

14. The method of claim 13 wherein the photopolymerizable composition is at a temperature of less than 60° C.

15. The method of claim 14 wherein the photopolymerizable composition is at a temperature of less than 25° C.

16. The method of claim 3 wherein the first encapsulant is heated to a temperature of less than 120° C.

17. The method of claim 16 wherein the first encapsulant is heated to a temperature of less than 60° C.

18. The method of claim 17 wherein the first encapsulant is heated to a temperature of less than 25° C.

19. The method of claim 2, further comprising the step of:
(D) providing room temperature conditions to further initiate hydrosilylation, thereby forming a second encapsulant.

20. The method of claim 1 wherein the first metal-containing catalyst and/or the second metal-containing catalyst comprise platinum.

21. The method of claim 20 wherein the first metal-containing catalyst is selected from the group consisting of Pt(II) β-diketonate complexes, (η⁵-cyclopentadienyl)tri(σ-aliphatic)platinum complexes, and C₇₋₂₀-aromatic substituted (η⁵-cyclopentadienyl)tri(σ-aliphatic)platinum complexes.

22. The method of claim 20 wherein the second metal-containing catalyst comprises a platinum vinylsiloxane complex.

23. The method of claim 2 wherein the actinic radiation has a wavelength of 600 nm or less.

24. The method of claim 23 wherein the actinic radiation has a wavelength of from 200 to 600 nm.

25. The method of claim 24 wherein the actinic radiation has at a wavelength of from 250 to 500 nm.

26. The method of claim 2 wherein the first encapsulant is a liquid, gel, elastomer, or non-elastic solid.

27. The method of claim 3 wherein the second encapsulant is a liquid, gel, elastomer, or non-elastic solid.

28. The method of claim 1 wherein the photopolymerizable composition has a refractive index of at least 1.34.

29. The method of claim 1 wherein the photopolymerizable composition has a refractive index of at least 1.50.

30. The method of claim 1 wherein the silicon-containing resin comprises one or more organosiloxanes.

31. The method of claim 30 wherein the one or more organosiloxanes comprises an organosiloxane having aliphatic unsaturation and silicon-bonded hydrogen in the same molecule.

32. The method of claim 30 wherein the one or more organosiloxanes comprises a first organosiloxane having aliphatic unsaturation and a second organosiloxane having silicon-bonded hydrogen.

33. The method of claim 32 wherein the first organosiloxane has the formula:
R¹ₐR²_{b}SiO_{(4-a-b)/2}
wherein:
R¹ is a monovalent, straight-chained, branched or cyclic, unsubstituted or substituted, hydrocarbon group that is free of aliphatic unsaturation and has from 1 to 18 carbon atoms;
R² is a monovalent hydrocarbon group having aliphatic unsaturation and from 2 to 10 carbon atoms;
a is 0, 1, 2, or 3;
b is 0, 1, 2, or 3; and
the sum a+b is 0, 1, 2, or 3;
with the proviso that there is on average at least one R² present per molecule.

34. The method of claim 33 wherein at least 90 mole percent of the R¹ groups are methyl.

35. The method of claim 33 wherein at least 20 mole percent of the R¹ groups are aryl, aralkyl, alkaryl, or combinations thereof.

36. The method of claim 35 wherein the R¹ groups are phenyl.

37. The method of claim 33 wherein the R² groups are vinyl or 5-hexenyl.

38. The method of claim 32 wherein the second organosiloxane has the formula:
R¹ₐH_{c}SiO_{(4-a-c)/2}
wherein:
R¹ is a monovalent, straight-chained, branched or cyclic, unsubstituted or substituted, hydrocarbon group that is free of aliphatic unsaturation and has from 1 to 18 carbon atoms;
a is 0, 1, 2, or 3;
c is 0, 1, or 2; and
the sum of a+c is 0, 1, 2, or 3;
with the proviso that there is on average at least one silicon-bonded hydrogen present per molecule.

39. The method of claim 38 wherein at least 90 mole percent of the R¹ groups are methyl.

40. The method of claim 38 wherein at least 20 mole percent of the R¹ groups are aryl, aralkyl, alkaryl, or combinations thereof.

41. The method of claim 40 wherein the R¹ groups are phenyl.

42. The method of claim 31 wherein the photopolymerizable material comprises an organosiloxane comprising the formulae:
R¹ₐR²_{b}SiO_{(4-a-b)/2} and R¹ₐH_{c}SiO_{(4-a-c)/2}
wherein:
R¹ is a monovalent, straight-chained, branched or cyclic, unsubstituted or substituted hydrocarbon group that is free of aliphatic unsaturation and has from 1 to 18 carbon atoms;
R² is a monovalent hydrocarbon group having aliphatic unsaturation and from 2 to 10 carbon atoms;
a is 0, 1, 2, or 3;
b is 0, 1, 2, or 3;
c is 0, 1, or 2;
the sum a+b is 0, 1, 2, or 3; and
the sum of a+c is 0, 1, 2, or 3;
with the proviso that there is on average at least one silicon-bonded hydrogen and at least one R² group is present per molecule.

43. The method of claim 42 wherein at least 90 mole percent of the R¹ groups are methyl.

44. The method of claim 42 wherein at least 20 mole percent of the R¹ groups are aryl, aralkyl, alkaryl, or combinations thereof.

45. The method of claim 44 wherein the R¹ groups are phenyl.

46. The method of claim 42 wherein the R² groups are vinyl or 5-hexenyl.

47. The method of claim 1 wherein the silicon-bonded hydrogen and the aliphatic unsaturation are present in a molar ratio of from 0.5 to 10.0.

48. The method of claim 47 wherein the silicon-bonded hydrogen and the aliphatic unsaturation are present in a molar ratio of from 0.8 to 4.0.

49. The method of claim 48 wherein the silicon-bonded hydrogen and the aliphatic unsaturation are present in a molar ratio of from 1.0 to 3.0.

50. The method of claim 1 wherein the photopolymerizable material comprises one or more additives selected from the group consisting of nonabsorbing metal oxide particles, semiconductor particles, phosphors, sensitizers, antioxidants, pigments, photoinitiators, catalyst inhibitors, adhesion promoters, and solvent.

51. The method of claim 2, further comprising the step of:
(D) simultaneously applying actinic radiation at a wavelength of 700 nm and heat to less than 150° C. to further initiate hydrosilylation, thereby forming a second encapsulant.

52. A light emitting device prepared according to the method of claim 1.

53. A light emitting device prepared according to the method of claim 2.

54. A light emitting device prepared according to the method of claim 3.

55. A light emitting device prepared according to the method of claim 51.

56. A photopolymerizable composition comprising:
a silicon-containing resin comprising silicon-bonded hydrogen and aliphatic unsaturation;
a first metal-containing catalyst that may be activated by actinic radiation; and
a second metal-containing catalyst that may be activated by heat but not the actinic radiation.

57. The photopolymerizable composition of claim 56, further comprising one or more additives selected from the group consisting of nonabsorbing metal oxide particles, semiconductor particles, phosphors, sensitizers, antioxidants, pigments, photoinitiators, catalyst inhibitors, adhesion promoters, and solvent.

58. The photopolymerizable composition of claim 56, further comprising one or more phosphors.
